(19) United States
(12) Patent Application Publication
(10) Pub. No.: US 2009/0181532 A1
(43) Pub. Date: Jul. 16, 2009

(54) INTEGRATION SCHEME FOR EXTENSION OF VIA OPENING DEPTH

(75) Inventors: David P. Colon, Newburgh, NY (US); Bradley P. Jones, Pleasant Valley, NY (US); Ramona Kei, Hopewell Junction, NY (US); Raymond G. Knauss, Wappingers Falls, NY (US); Richard P. Volant, New Fairfield, CT (US); Yun-Yu Wang, Poughquag, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/971,996

(22) Filed: Jan. 10, 2008

(51) Int. Cl. H01L 21/44

(52) U.S. Cl. 438/612

(57) ABSTRACT

An interconnect structure having an incomplete via opening is processed to deepen a via opening and to expose a metal line. In case the interconnect structure comprises a metal pad or a blanket metal layer, the metal pad or the metal layer is removed selective to an underlying dielectric layer to expose the incomplete via opening. Another dielectric layer is formed within the incomplete via opening to compensated for differences in the total dielectric thickness above the metal line relative to an optimal dielectric stack. A photoresist is applied thereupon and patterned. An anisotropic etch process for formation of a normal via opening may be employed with no or minimal modification to form a proper via opening and to expose the metal line. A metal pad is formed upon the metal line so that electrical contact is provided between the metal pad and the metal line.

### FIELD OF THE INVENTION

The present invention relates to methods of forming a semiconductor structure, and particularly to methods of extending the depth of a via opening to enable exposure of an underlying metal line and formation of a contact thereupon.

### BACKGROUND OF THE INVENTION

Manufacture of a semiconductor chip employs formation of an interconnect structure in back-end-of-line (BEOL) processing steps. The interconnect structure comprises multiple levels of metal lines and metal vias. The metal lines provide horizontal conduction paths within the same interconnect level, while the metal vias provide vertical conduction paths between neighboring interconnect levels. Typically, the interconnect structure further comprises metal pads at a top level of the interconnect structure to provide electrical paths for communicating signals into and out of the semiconductor chip. For this purpose, the metal pads may be employed as wirebond pads.

Formation of a functional interconnect structure requires sequential performance of multiple proper processing steps on a semiconductor substrate. The sequence of the processing steps is termed in the art as “routing,” or “process integration.” Maintaining variations of an individual process within allowable limits, or “process specifications,” which is typically set by yield considerations, is termed in the art as “process control.” Proper routing and process control are essential in the manufacture of the functional interconnect structure.

A prior art interconnect structure for formation of a metal pad is described herein to illustrate a particular example of routing and process control issues involved in the manufacture of interconnect structures. Referring to FIG. 1, a prior art interconnect structure comprises a top level interconnect layer 8, which contains an interconnect level dielectric layer 10, metal vias 12, and metal lines 14. The interconnect level dielectric layer 8 typically comprises silicon oxide. The metal vias 12 and the metal lines 14 typically comprise Cu. Lower level interconnect structures (not shown) and devices formed on a semiconductor substrate (not shown) are located beneath the top level interconnect layer 8. A dielectric cap layer 20 is formed directly on the metal lines 14 and the top level interconnect layer 8. A first dielectric layer 30 and a second dielectric layer 32 are formed on the dielectric cap layer 20. For example, the first dielectric layer 30 may comprise silicon oxide and the second dielectric layer 32 may comprise silicon nitride. The thickness of the first dielectric layer 30 may be from about 200 nm to about 700 nm, and thickness of the second dielectric layer 34 may be from about 200 nm to about 600 nm.

Referring to FIG. 2, a photoresist 47 is applied to the top surface of the second dielectric layer 32 and lithographically patterned. The pattern in the photoresist 47 is transferred into the second dielectric layer 32, the first dielectric layer 30, and the dielectric cap layer 20 by an anisotropic etch, such as a reactive ion etch, to expose a top surface of one of the metal lines 14. The depth of a via opening VO located in the second dielectric layer 32, the first dielectric layer 30, and the dielectric cap layer 20 and formed by the anisotropic etch is at least equal to a standard total dielectric thickness to, which is the sum of the thicknesses of the second dielectric layer 32, the first dielectric layer 30, and the dielectric cap layer 20. Typically, some overetch into the interconnect level dielectric layer 10 is performed to insure that the entirety of the surface of the metal line 14 within the via opening VO in the dielectric cap layer 20 is exposed after the anisotropic etch. Too much overetch into the interconnect level dielectric layer 10 is undesirable since the void fill capability of metal layers to be subsequently formed is typically limited, and consequently may form voids within the interconnect level dielectric layer 10. Thus, the anisotropic etch is optimized to etch the material of the second dielectric layer 32, the first dielectric layer 30, and the dielectric cap layer 20 to a depth that exceeds the standard total dielectric thickness to by a small overetch margin. The photoresist 47 is subsequently removed.

Referring to FIG. 3, at least one metallic liner layer and a metal layer are deposited within the via opening VO and lithographically patterned to form a metal pad comprising a pad liner portion 40 and a pad metal portion 50. The pad metal portion 50 and the pad liner portion 40 collectively constitute the metal pad (40, 50), which may function as a wirebond pad. The metal pad (40, 50) is electrically connected to one of the metal lines 14.

The exemplary prior art structure of FIG. 3 represents a functional interconnect structure that is manufactured when proper process control and routing is employed in the manufacture process. For the metal pad (40, 50) to be properly formed with solid electrical contact with one of the metal lines 14, the total thickness of the dielectric cap layer 20, the first dielectric layer 30, and the second dielectric layer 32 need to be within a specification range. Further, the anisotropic etch process needs to completely remove all dielectric material from above the portion of the metal lines 14 within the via opening VO in the stack of the dielectric cap layer 20, the first dielectric layer 30, and the second dielectric layer 32.

An increase of the total thickness of the dielectric cap layer 20, the first dielectric layer 30, and the second dielectric layer 32 may be caused by failure in process control or by erroneous routing such as repeated deposition of any one of the dielectric cap layer 20, the first dielectric layer 30, and the second dielectric layer 32. Such an increase in the total thickness may result in an incomplete via opening VO that does not expose a top surface of the metal lines 14 and/or a metal pad (40, 50) that does not contact the metal lines 14. Absent intervention at this point, a resulting semiconductor chip is a non-functional chip due to the electrically disconnected metal pad (40, 50).

In view of the above, there exists a need for integration schemes that enables proper formation of a metal pad that contacts a metal line within an interconnect level dielectric layer after formation of an incomplete via opening that does not expose the metal line.

In general, formation of the incomplete via opening may be detected at any of the various processing steps thereafter including a step after removal of the photoresist 47 and prior to formation of the at least one metallic liner layer, a step after formation of the metal layer and prior to patterning of the metal layer, or a step after patterning of the metal pad (40, 50). Therefore, there is a need for integration schemes for forming a proper metal pad contacting the metal line within the interconnect level dielectric layer from interconnect structures at various steps after the formation of the incomplete via opening.

### SUMMARY OF THE INVENTION

The present invention addresses the needs described above by providing integration schemes for forming a proper metal pad contacting a metal line within an interconnect level dielectric layer from interconnect structures at various steps after the formation of an incomplete via opening.

In the present invention, an interconnect structure having an incomplete via opening that does not expose a top surface of a metal line underneath is processed to deepen the via opening and to expose the metal line. In case the interconnect structure comprises a metal pad or a blanket metal layer, the metal pad or the metal layer is removed selective to an underlying dielectric layer to expose the incomplete via opening. Another dielectric layer is formed within the incomplete via opening to compensated for differences in the total dielectric thickness above the metal line relative to an optimal dielectric stack. A photoresist is applied thereupon and patterned. An anisotropic etch process for formation of a normal via opening may be employed with no or minimal modification to form a proper via opening and to expose the metal line. A metal pad is formed upon the metal line so that electrical contact is provided between the metal pad and the metal line.

According to an aspect of the present invention, a method of modifying a first interconnect structure is provided, which comprises:

providing an interconnect structure comprising:
a metal line embedded in an interconnect level dielectric layer;
at least one dielectric layer containing a via opening, wherein a via opening is separated from the metal line by the at least one dielectric layer; and
a metal pad filling the via opening;

removing the metal pad selective to the at least one dielectric layer and exposing the via opening;

forming a supplementary dielectric layer in the via opening, wherein the sum of a thickness of the supplementary dielectric layer and a thickness of the at least one dielectric layer directly above the metal line is substantially equal to a predefined target thickness; and

patterning the supplementary dielectric layer and the at least one dielectric layer directly above the metal line to expose the metal line.

According to another aspect of the present invention, a method of modifying a second interconnect structure is provided, which comprises:

providing an interconnect structure comprising:
a metal line embedded in an interconnect level dielectric layer;
at least one dielectric layer containing a via opening, wherein a via opening is separated from the metal line by the at least one dielectric layer; and
at least one metallic liner located directly on the at least one dielectric layer and filling the via opening; and
a metal layer located directly on the at least one metallic liner;

removing the metal layer and the at least one metallic liner selective to the at least one dielectric layer and exposing the via opening;

forming a supplementary dielectric layer in the via opening, wherein the sum of a thickness of the supplementary dielectric layer and a thickness of the at least one dielectric layer directly above the metal line is substantially equal to a predefined target thickness; and

patterning the supplementary dielectric layer and the at least one dielectric layer directly above the metal line to expose the metal line.

According to yet another aspect of the present invention, a method of modifying a third interconnect structure is provided, which comprises:

providing an interconnect structure comprising:
a metal line embedded in an interconnect level dielectric layer; and
at least one dielectric layer containing a via opening, wherein a via opening is separated from the metal line by the at least one dielectric layer;

forming a supplementary dielectric layer in the via opening, wherein the sum of a thickness of the supplementary dielectric layer and a thickness of the at least one dielectric layer directly above the metal line is substantially equal to a predefined target thickness; and

patterning the supplementary dielectric layer and the at least one dielectric layer directly above the metal line to expose the metal line.

In one embodiment, the above methods further comprise forming at least one metallic liner layer directly on the metal line after the metal line is exposed.

In another embodiment, the at least one metallic layer comprises at least one of a TaN layer, a Ti layer, and a TiN layer.

In yet another embodiment, the at least one metallic layer comprises a stack, from bottom to top, of a TaN layer, a Ti layer, and a TiN layer.

In still another embodiment, the above methods further comprise forming a metal layer directly on the at least one metallic layer.

In still yet another embodiment, the metal layer comprise Al and has a thickness from about 0.8 μm to about 5.0 μm.

In a further embodiment, the at least one dielectric layer comprises:

a dielectric cap layer abutting the metal line and the interconnect level dielectric layer;

a first dielectric layer abutting the dielectric cap layer; and

a second dielectric layer abutting the first dielectric layer.

In an even further embodiment, the second dielectric layer and the supplementary dielectric layer comprise a same material.

In a yet further embodiment, the first dielectric layer comprises silicon oxide and the second dielectric layer comprises silicon nitride.

### BRIEF DESCRIPTION OF THE DRAWINGS

FIGS. 1-3 are sequential vertical cross-sectional views of a prior art interconnect structure.

FIGS. 4-8 are sequential vertical cross-sectional views of a first exemplary interconnect structure according to a first embodiment of the present invention.

FIGS. 9-13 are sequential vertical cross-sectional views of a second exemplary interconnect structure according to a second embodiment of the present invention.

FIG. 14 is a vertical cross-sectional view of a third exemplary interconnect structure according to a third embodiment of the present invention.

### DETAILED DESCRIPTION OF THE INVENTION

As stated above, the present invention relates to methods of extending the depth of a via opening to enable exposure of an underlying metal line and formation of a contact thereupon, which is now described in detail with accompanying figures. It is noted that like and corresponding elements are referred to by like reference numerals.

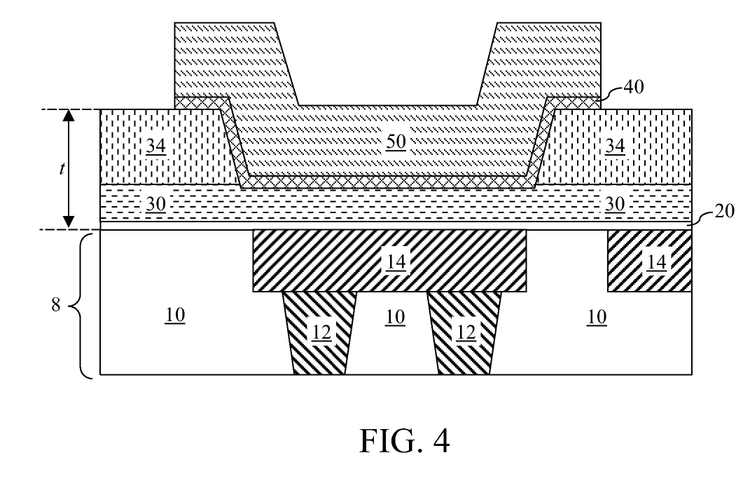

Referring to FIG. 4, a first exemplary interconnect structure according to a first embodiment of the present invention comprises a top level interconnect layer 8, which contains an interconnect level dielectric layer 10, metal vias 12, and metal lines 14. The interconnect level dielectric layer 10 typically comprises a silicon oxide such as undoped silicate glass (USG) or a fluorosilicate glass (FSG). The metal vias 12 and the metal lines 14 typically comprise Cu, and may include metallic liners (not shown) that promote adhesion of the metal vias 12 and the metal lines 14 within the interconnect level dielectric layer 10. Lower level interconnect structures (not shown) and devices formed on a semiconductor substrate (not shown) are located beneath the top level interconnect layer 8. The top level interconnect layer 8 may be substantially the same as in the exemplary prior art interconnect structure.

A dielectric cap layer 20, a first dielectric layer 30, and a second dielectric layer 34, which is herein collectively referred to as “at least one dielectric layer” (20, 30, 34), are sequentially formed on the metal lines 14 and the interconnect level dielectric layer 10. The dielectric cap layer 20 typically comprises silicon nitride such as ultraviolet treated silicon nitride formed by plasma enhanced chemical vapor deposition (PECVD) followed by ultraviolet treatment or high density plasma silicon nitride formed by high density plasma chemical vapor deposition (HDPCVD). The dielectric cap layer typically has a thickness from about 5 nm to about 80 nm, although lesser and greater thicknesses are also contemplated herein. The first dielectric layer 30 and the second dielectric layer 34 may comprise the same material, or different materials. For example, the first dielectric layer 30 may comprise silicon oxide and the second dielectric layer 34 may comprise silicon nitride. The thickness of the first dielectric layer 30 may be from about 200 nm to about 700 nm, and thickness of the second dielectric layer 34 may be greater than 600 nm.

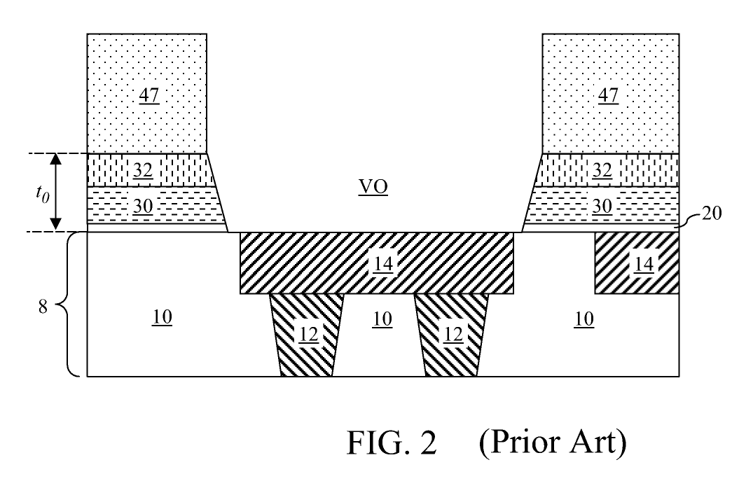

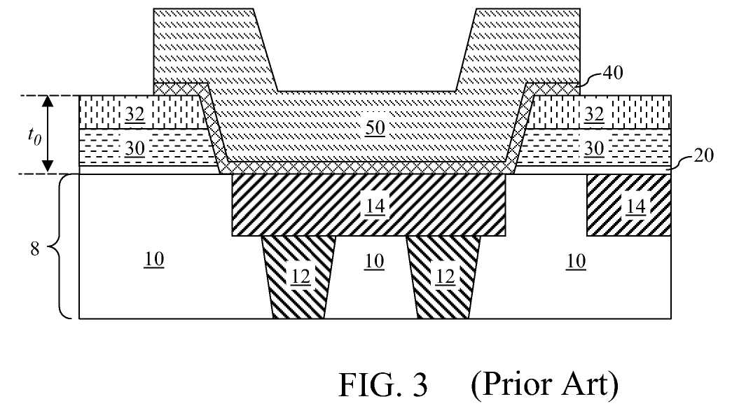

The total dielectric thickness t of the first exemplary interconnect structure exceeds the standard total dielectric thickness t₀ of the exemplary prior art interconnect structure of FIG. 2. Such an increase in the total dielectric thickness t may be caused by failure in process control and/or routing errors by which more material is deposited within any of the dielectric cap layer 20, the first dielectric layer 30, and/or the second dielectric layer 34. While the increase of the total dielectric thickness t may be caused by an increase in thickness in any of the second dielectric layer 34, the first dielectric layer 30, and the dielectric cap layer 20 compared with the corresponding layers, which include the second dielectric layer 32, the first dielectric layer 30, and the dielectric cap layer 20 of FIG. 3, for the purposes of description of the present invention, an increase in the thickness of the second dielectric layer 34 in FIG. 4 relative to the thickness of the second dielectric layer 32 in FIG. 3 is assumed. Variations in which at least one of the first dielectric layer 30 and the dielectric cap layer 20 is thicker than corresponding layer in the exemplary interconnect structure of FIG. 3 are explicitly contemplated herein. Variations in which an extra dielectric layer is present on top of, or between, the dielectric cap layer 20, the first dielectric layer 30, and the second dielectric layer 34 compared with the exemplary prior art interconnect structure of FIG. 3 are also explicitly contemplated herein.

A photoresist (not shown) is applied to the top surface of the second dielectric layer 34 and lithographically patterned. The pattern in the photoresist is transferred into the second dielectric layer 34, the first dielectric layer 30, and the dielectric cap layer 20 by an anisotropic etch which is substantially the same as the anisotropic etch in the prior art processing steps of FIG. 2. Due to the increase in the total dielectric thickness t compared with the standard total dielectric thickness t₀, however, the anisotropic etch stops prior to exposing a top surface of the metal lines 14. Thus, a portion of the at least one dielectric layer (20, 30, 34) separates the via opening from the metal lines 14. Unless the failure to expose a surface of the metal lines 14 is detected prior to removal of the photoresist, the photoresist is subsequently removed.

Thereafter, at least one metallic liner layer and a metal layer are deposited within the via opening and lithographically patterned to form a metal pad comprising a pad liner portion 40 and a pad metal portion 50. The pad liner portion 40 typically comprises a stack of a TaN layer, a Ti layer, and a TiN layer, from bottom to top. For example, the thickness of the TaN layer may be about 70 nm, the thickness of the Ti layer may be about 25 nm, and the thickness of the TiN layer may be about 25 nm, although variations in the thicknesses of the various metallic liner layers may vary depending on application. The pad metal portion 50 comprises Al and has a thickness from about 0.8 μm to about 5.0 μm. The pad metal portion 50 and the pad liner portion 40 collectively constitute the metal pad (40, 50), which may function as a wirebond pad. The metal pad (40, 50) is disjoined from the metal lines 14, i.e., electrical contact is not provided between the metal pad (40, 50) and the metal lines 14.

While two dielectric layers are formed above the dielectric cap layer 20 for the purposes of description of the present invention in the first exemplary interconnect structure, the present invention is applicable irrespective of the number of dielectric layers above the dielectric cap layer 20 as long as the total dielectric thickness t exceeds a maximum allowed thickness for the standard total dielectric thickness t₀ so that the via opening does not expose the metal lines 14. The number of dielectric layer(s) may be any positive integer including 1 in the present invention.

Electrical isolation of the metal pad (40, 50) from the metal lines 14 causes functional failure of the first exemplary interconnect structure. Further processing of the first exemplary interconnect structure only produces a non-functional semiconductor chip. The present invention provides remedy for this situation.

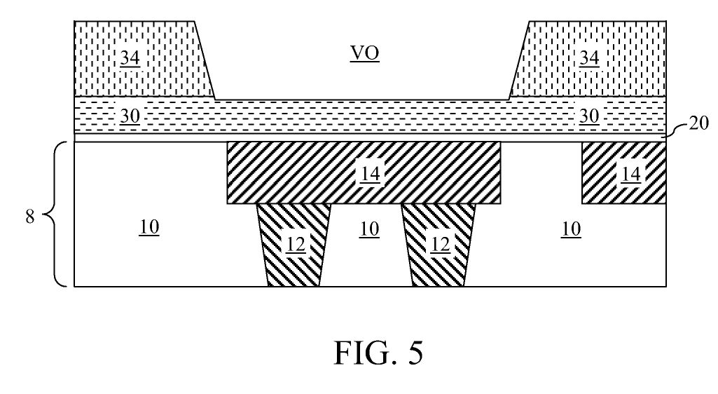

Referring to FIG. 5, the metal pad (40, 50) is removed selective to the at least one dielectric layer (20, 30, 34). Specifically, a first wet etch employing hydrofluoric acid is employed to remove residual dielectric oxide such as AlOₓ and SiO_{y}, wherein x and y are both in the range from about 1 to about 3, from the surfaces of the metal pad (40, 50) and exposed surfaces of the second dielectric layer 34. An aerosol clean, which is a cryogenic cleaning process in which foreign material on exposed surfaces is removed by momentum transfer from atoms impinging on the surface at a glancing angle, is performed to remove any residual material from the surfaces of the metal pad (40, 50) and the second dielectric layer 34.

A second wet etch employing sulfuric peroxide is then employed to remove the metal pad (40, 50), which includes the pad metal portion 50 comprising Al and the pad liner portion 40, selective to the at least one dielectric layer (20, 30, 34). In case the pad liner portion 40 comprises a stack, from bottom to top, of a TaN layer, a Ti layer, and a TiN layer, the second wet etch may remove the entirety of the pad metal portion 50, the TiN layer, and the Ti layer. A touch up etch, which may be a reactive ion etch, may be employed to removed the remainder of the pad liner portion 40, which may comprise the TaN layer.

A via opening VO is thus within the second dielectric layer 34. The first dielectric layer 30 may, or may not, be exposed at the bottom of the via opening VO. Typically, the dielectric cap layer 20 is not exposed at this point. A portion of the at least one dielectric layer (20, 30, 34) is thus present between the bottom surface of the via opening VO and the top surface of the metal lines 14. The bottom surface of the via opening VO may be located in the first dielectric layer 30, or the second dielectric layer 34.

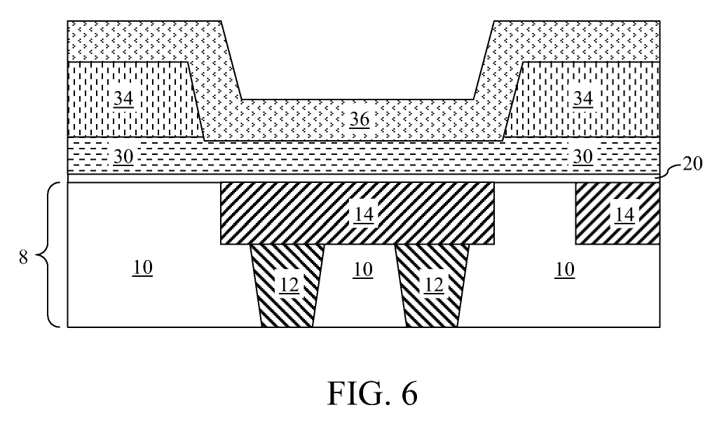

Referring to FIG. 6, a supplementary dielectric layer 36 is formed on exposed surfaces including the surfaces of the via opening VO of FIG. 5. The supplementary dielectric layer 36 comprises a dielectric material such as silicon oxide and/or silicon nitride. The thickness of the supplementary dielectric layer 36 is optimized such that the sum of the thickness of the supplementary dielectric layer 36 and the thickness of the portion of the at least one dielectric layer (20, 30, 34) directly beneath the recessed area of the supplementary dielectric layer 36 is substantially equal to a predetermined target thickness. The supplementary dielectric layer 36 may, or may not, comprise the same material as the first dielectric layer 30 or the second dielectric material layer 34.

The predetermined target thickness may substantially match the standard total dielectric thickness t₀ if the material of the supplementary dielectric layer 36 has a similar level of etch resistance as the material of the first dielectric layer 30 and/or the second dielectric layer 34. The total etch resistance of the supplementary dielectric layer 36 and the portion of the at least one dielectric layer (20, 30, 34) directly beneath the recessed area of the supplementary dielectric layer 36 may substantially match the total etch resistance of the at least one dielectric layer (20, 30, 32) of FIG. 2 having the standard total dielectric thickness t₀. An anisotropic etch that forms a via opening VO employed in the exemplary prior art structure of FIG. 2 may be subsequently employed in this case to expose the top surfaces of the metal lines 14.

Preferably, the supplementary dielectric layer 36 and the second dielectric layer 34 comprise the same material. For example, the supplementary dielectric layer 36 and the second dielectric layer 34 may comprise silicon nitride and the first dielectric layer 30 may comprise silicon oxide. The stack of the supplementary dielectric layer 36 and the portion of the at least one dielectric layer (20, 30, 34) directly beneath the recessed area of the supplementary dielectric layer 36 closely matches a normal dielectric stack of FIG. 2, which comprises the dielectric cap layer 30, the first dielectric layer 30, and the second dielectric layer 32, having the standard total dielectric thickness t₀.

Processing steps intended to provide a clean surface may be performed at this step. Exemplary cleaning process that may be employed include an O₂ plasma clean that removes foreign material from the surface of the supplementary dielectric layer 36.

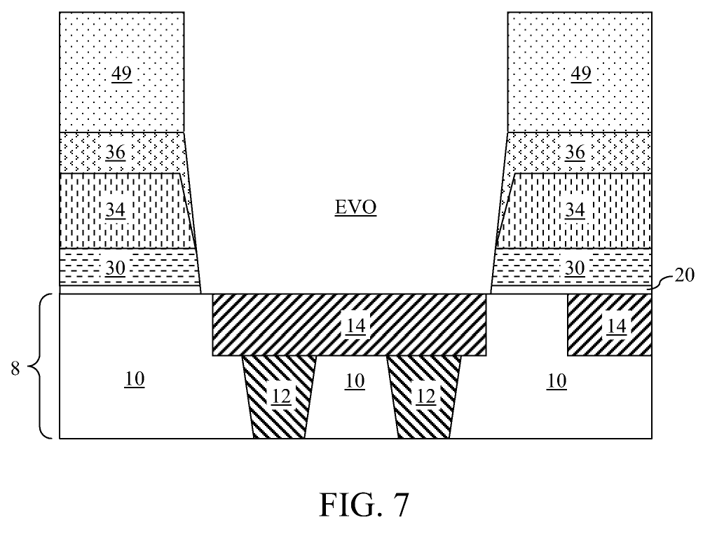

Referring to FIG. 7, a photoresist 49 is applied to the surface of the supplementary dielectric layer 36 and lithographically patterned such that the pattern in the photoresist 49 is substantially identical to the pattern the recessed region of the supplementary dielectric layer 36. Thus, the pattern in the photoresist 49 substantially coincides with the via opening VO in FIG. 5. The lithography process of this step may be substantially the same as the lithography step employed in forming the exemplary prior art structure of FIG. 2.

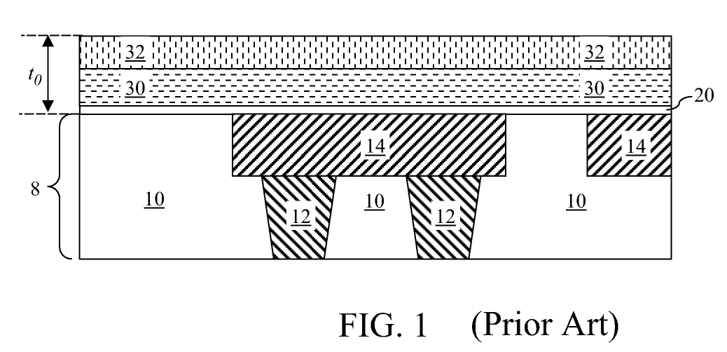

An anisotropic etch process that is substantially the same as the anisotropic etch process employed to form the via opening VO in the exemplary prior art interconnect structure of FIG. 2. Since the total etch resistance of the stack of the supplementary dielectric layer 36 and the portion of the at least one dielectric layer (20, 30, 34) in the recessed portion of the supplementary dielectric layer 36 substantially matches the total etch resistance of the at least one dielectric layer (20, 30, 34) in the exemplary prior art interconnect structure of FIG. 1, the anisotropic etch removes the supplementary dielectric layer 36 and the portion of the at least one dielectric layer (20, 30, 34) from the recessed portion of the supplementary dielectric layer 36 with an optimal amount of overetch.

Further, the composition and the total thickness of the stack of the supplementary dielectric layer 36 and the portion of the at least one dielectric layer (20, 30, 34) in the recessed portion of the supplementary dielectric layer 36 may match the composition of the entirety of the at least one dielectric layer (20, 30, 32) of FIG. 1. For example, the bottom surface of the supplementary dielectric layer 36 may be substantially level with the interface between the first dielectric layer 30 and the second dielectric layer, and the thickness and composition of the supplementary dielectric layer 36 may substantially match the thickness and composition of the second dielectric layer 32 of FIG. 1. Thus, the same anisotropic etch as one employed to form the exemplary prior art interconnect structure of FIG. 2 may be employed with no or minimal modification to enable formation of an “extended” via opening EVO that exposes the metal lines 14. The extended via opening EVO is deeper than the via opening VO of the exemplary prior art interconnect structure of FIG. 2 due to the thickness increase of the stack of the at least one dielectric layer (20, 30, 34) outside the extended via opening EVO of the first exemplary interconnect structure compared with the standard total dielectric thickness t₀ of the at least one dielectric layer (20, 30, 34) of FIG. 1.

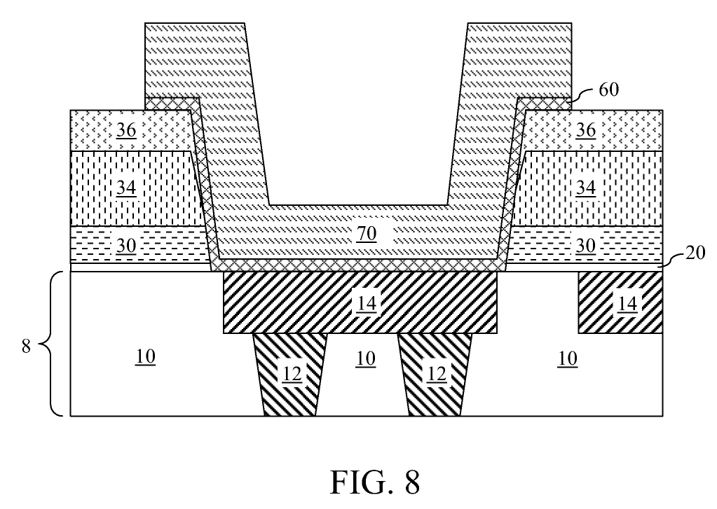

Referring to FIG. 8, at least one replacement metallic liner layer and a replacement metal layer are deposited within the via opening and lithographically patterned to form a replacement metal pad comprising a replacement pad liner portion 60 and a replacement pad metal portion 70. The at least one replacement metallic liner layer, and consequently, the replacement pad liner portion 60, may have the same vertical layer structure and composition as the pad liner portion 40. Likewise, the replacement metal layer, and consequently, the replacement pad metal portion 70, may have the same composition as the pad metal portion 50. Thus, in composition and thickness, the replacement pad liner portion 60 may be the same as the pad liner portion 40, the replacement metal pad portion 70 may be the same as the metal pad portion 70, and the replacement metal pad (60, 70) may be the same as the metal pad (40, 50). While the metal pad (40, 50) of FIG. 4 does not contact the metal lines 14 embedded in the top level interconnect layer 8, the replacement metal pad (60, 70) contacts the metal lines 14 embedded in the top level interconnect layer 8.

The replacement pad liner portion 60 typically comprises a stack of a TaN layer, a Ti layer, and a TiN layer, from bottom to top. For example, the thickness of the TaN layer may be about 70 nm, the thickness of the Ti layer may be about 25 nm, and the thickness of the TiN layer may be about 25 nm, although variations in the thicknesses of the various metallic liner layers may vary depending on application. The replacement pad metal portion 70 comprises Al and has a thickness from about 0.8 μm to about 5.0 μm. The replacement pad metal portion 70 and the replacement pad liner portion 60 collectively constitute the replacement metal pad (60, 70), which may function as a wirebond pad. The replacement metal pad (60, 70) is electrically connected to the metal lines 14.

It is noted that the label “replacement” that is assigned to the replacement pad liner portion 60, the replacement metal pad portion 70, and the replacement metal pad (60, 70) only denotes the characteristics of these elements as replacement elements for each of the pad liner portion 40, the metal pad portion 50, and the metal pad (40, 50), and that these elements may be properly termed without the label “replacement” when such characteristics are not considered.

The first embodiment of the present invention thus provides a method, or an integration scheme, for removing a metal pad (40, 50) that is not electrically connected to metal lines 14 within a top level interconnect layer 8 and subsequently forming a replacement metal pad (60, 70) that is electrically connected to the metal lines 14, thus repairing a critical structural problem that would have resulted in a non-functional semiconductor chip and providing a functional electrical contact between the metal lines 14 and the replacement metal pad (60, 70).

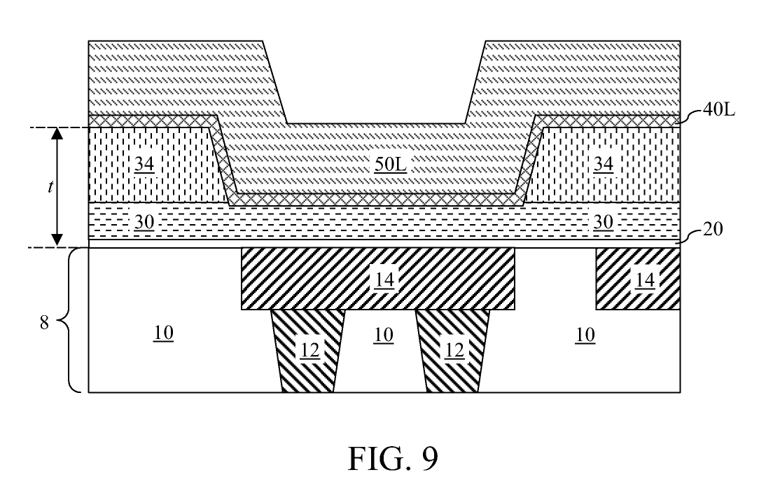

Referring to FIG. 9, a second exemplary interconnect structure according to a second embodiment of the present invention may be formed by a similar failure in process control and/or routing errors as in the first embodiment. In the second embodiment, identical structures and processing steps are employed as in the first exemplary interconnect structure of the first embodiment up to the formation of a via opening. A portion of the at least one dielectric layer (20, 30, 34) separates the via opening from the metal lines 14 as in the first embodiment.

At least one metallic liner layer 40L and a metal layer 50L are deposited within the via opening. The at least one metallic liner layer 40L may have the same vertical stack as the pad liner portion 40 of FIG. 4 in the first exemplary interconnect structure. The at least one metallic liner layer 40L typically comprises a stack of a TaN layer, a Ti layer, and a TiN layer, from bottom to top. For example, the thickness of the TaN layer may be about 70 nm, the thickness of the Ti layer may be about 25 nm, and the thickness of the TiN layer may be about 25 nm, although variations in the thicknesses of the various metallic liner layers may vary depending on application. The metal layer 50L may have the same composition and thickness as the pad metal portion 50 of FIG. 4 in the first exemplary interconnect structure. For example, the metal layer 50L comprises Al and has a thickness from about 0.8 μm to about 5.0 μm. The at least one metallic layer 40L and the metal layer 50L are disjoined from the metal lines 14, i.e., electrical contact is not provided between the at least one metallic layer 40L and the metal lines 14. Further patterning of the least one metallic liner layer 40L and the metal layer 50L would result in a non-functional metal pad due to lack of contact to the metal lines 14 underneath.

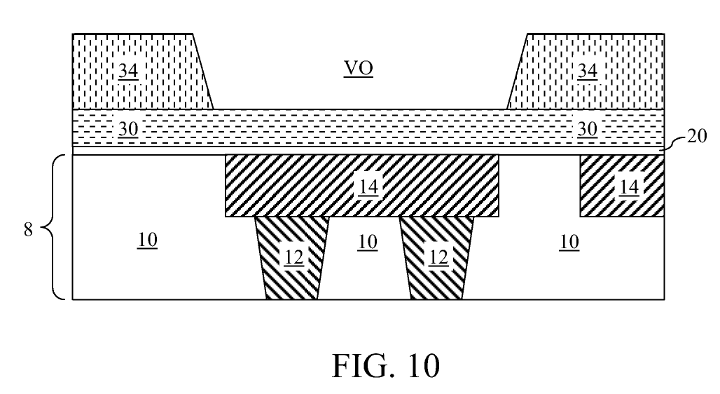

Referring to FIG. 10, a wet etch employing sulfuric peroxide is employed to remove the least one metallic liner layer 40L and the metal layer 50L selective to the at least one dielectric layer (20, 30, 34). In case the at least one metallic liner layer 40L comprises a stack, from bottom to top, of a TaN layer, a Ti layer, and a TiN layer, the wet etch may remove the entirety of the pad metal portion 50, the TiN layer, and the Ti layer. A touch up etch, which may be a reactive ion etch, may be employed to removed the remainder of the at least one metallic liner layer 40L, which may comprise the TaN layer.

A via opening VO is thus within the second dielectric layer 34. The first dielectric layer 30 may, or may not, be exposed at the bottom of the via opening VO. Typically, the dielectric cap layer 20 is not exposed at this point. A portion of the at least one dielectric layer (20, 30, 34) is thus present between the bottom surface of the via opening VO and the top surface of the metal lines 14. The bottom surface of the via opening VO may be located in the first dielectric layer 30, or the second dielectric layer 40.

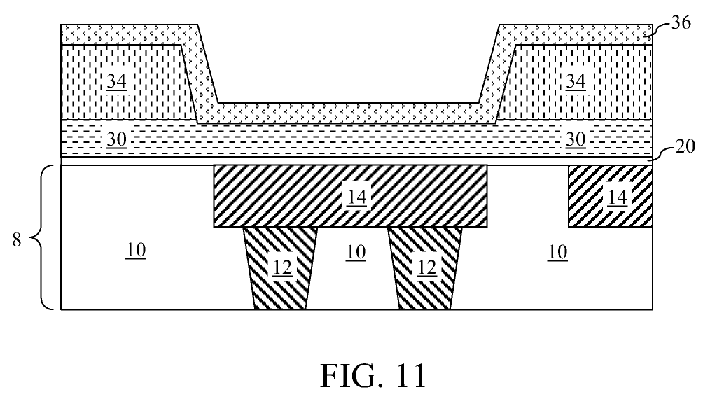

Referring to FIG. 11, a supplementary dielectric layer 36 is formed on exposed surfaces including the surfaces of the via opening VO of FIG. 10. The supplementary dielectric layer 36 comprises a dielectric material such as silicon oxide and/or silicon nitride. The thickness of the supplementary dielectric layer 36 is optimized such that the sum of the thickness of the supplementary dielectric layer 36 and the thickness of the portion of the at least one dielectric layer (20, 30, 34) directly beneath the recessed area of the supplementary dielectric layer 36 is substantially equal to a predetermined target thickness. The supplementary dielectric layer 36 may, or may not, comprise the same material as the first dielectric layer 30 or the second dielectric material layer 34.

The thickness and composition of the supplementary dielectric layer 36 may be the same as in the first embodiment, and determined based on the same consideration employed in the first embodiment. Processing steps intended to provide a clean surface may be performed thereafter. Exemplary cleaning process that may be employed include an O₂ plasma clean that removes foreign material from the surface of the supplementary dielectric layer 36.

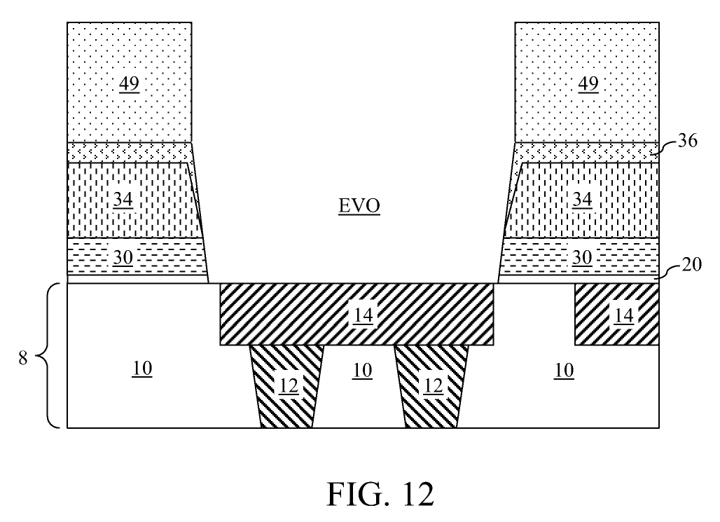

Referring to FIG. 12, a photoresist 49 is applied to the surface of the supplementary dielectric layer 36 and lithographically patterned such that the pattern in the photoresist 49 is substantially identical to the pattern the recessed region of the supplementary dielectric layer 36 in the same manner as in the first embodiment. An anisotropic etch process that is substantially the same as the anisotropic etch process employed to form the via opening VO in the exemplary prior art interconnect structure of FIG. 2. As in the first embodiment, the anisotropic etch removes the supplementary dielectric layer 36 and the portion of the at least one dielectric layer (20, 30, 34) from the recessed portion of the supplementary dielectric layer 36 with an optimal amount of overetch, since the total etch resistance of the stack of the supplementary dielectric layer 36 and the portion of the at least one dielectric layer (20, 30, 34) in the recessed portion of the supplementary dielectric layer 36 substantially match the total etch resistance of the at least one dielectric layer (20, 30, 34) in the exemplary prior art interconnect structure of FIG. 1.

As in the first embodiment, the same anisotropic etch as one employed to form the exemplary prior art interconnect structure of FIG. 2 may be employed with no or minimal modification to enable formation of an “extended” via opening EVO that exposes the metal lines 14. The extended via opening EVO is deeper than the via opening VO of the exemplary prior art interconnect structure of FIG. 2 due to the thickness increase of the stack of the at least one dielectric layer (20, 30, 34) outside the extended via opening EVO of the first exemplary interconnect structure compared with the standard total dielectric thickness to of the at least one dielectric layer (20, 30, 34) of FIG. 1.

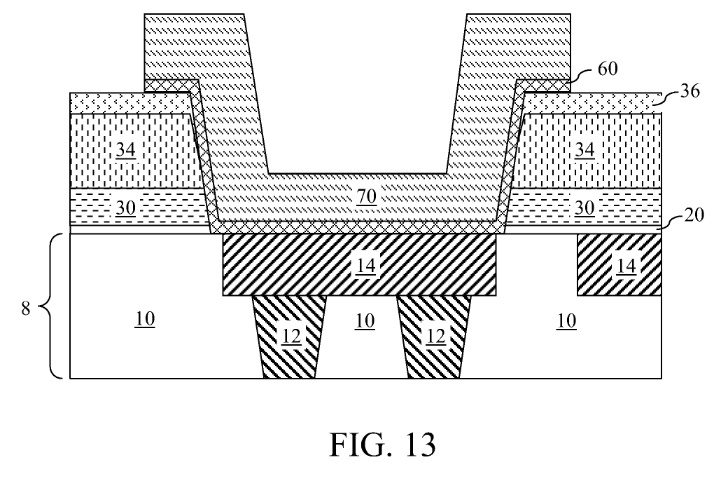

Referring to FIG. 13, at least one replacement metallic liner layer and a replacement metal layer are deposited within the via opening and lithographically patterned to form a replacement metal pad comprising a replacement pad liner portion 60 and a replacement pad metal portion 70 in the same manner as in the first embodiment. The replacement pad liner portion 60 and the replacement pad metal portion 70 have the same composition and thickness and provides the same functionality as in the first embodiment. Specifically, the replacement metal pad (60, 70) contacts the metal lines 14 embedded in the top metal interconnect layer 8. The replacement pad metal portion 70 and the replacement pad liner portion 60 collectively constitute the replacement metal pad (60, 70), which may function as a wirebond pad.

The second embodiment of the present invention thus provides a method, or an integration scheme, for removing at least one metallic liner layer 40L and a metal layer 50L that is not electrically connected to metal lines 14 within a top level interconnect layer 8 and subsequently forming a replacement metal pad (60, 70) that is electrically connected to the metal lines 14, thus repairing a critical structural problem that would have resulted in a non-functional semiconductor chip and providing a functional electrical contact between the metal lines 14 and the replacement metal pad (60, 70).

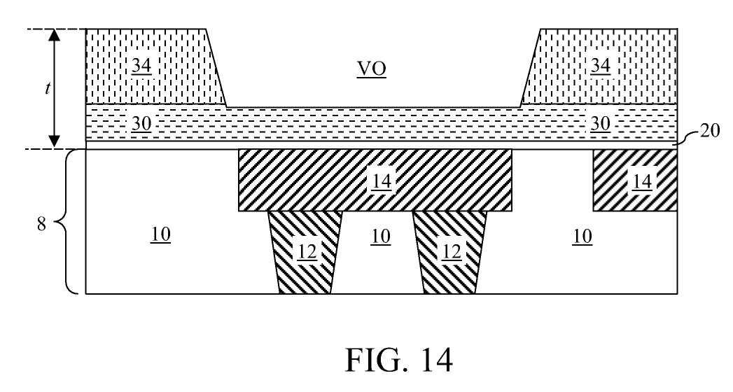

Referring to FIG. 14, a third exemplary interconnect structure according to a third embodiment of the present invention may be formed by a similar failure in process control and/or routing errors as in the first embodiment. In the third embodiment, identical structures and processing steps are employed as in the first exemplary interconnect structure of the first embodiment up to the formation of a via opening to provide the third exemplary interconnect structure. No metallic liner layer or metal layer is deposited within the via opening at this point. A portion of the at least one dielectric layer (20, 30, 34) separates the via opening from the metal lines 14 as in the first embodiment.

Processing steps of the second embodiment corresponding to FIGS. 11-13 are subsequently performed to provide the same interconnect structure of FIG. 13 of the second embodiment including deposition of the supplementary dielectric layer 36, application of a photoresist 49 and patterning thereof, formation of an extended via opening EVO, and formation of a replacement metal pad (60, 70). The processing steps and structures are identical to the counterparts in the second embodiment.

The third embodiment of the present invention thus provides a method, or an integration scheme, for modifying an interconnect structure containing a via opening VO that does not expose metal lines 14, while not containing any metallic liner layer or a metal layer. The via opening VO is extended downward to form an extended via opening EVO that exposes metal lines 14 within a top level interconnect layer 8. A replacement metal pad (60, 70) that is electrically connected to the metal lines 14 is subsequently formed, thus repairing a critical structural problem that would have resulted in a non-functional semiconductor chip and providing a functional electrical contact between the metal lines 14 and the replacement metal pad (60, 70).

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A method of modifying an interconnect structure comprising:
providing an interconnect structure comprising:
a metal line embedded in an interconnect level dielectric layer;
at least one dielectric layer containing a via opening, wherein a via opening is separated from said metal line by said at least one dielectric layer; and
a metal pad filling said via opening;
removing said metal pad selective to said at least one dielectric layer and exposing said via opening;
forming a supplementary dielectric layer in said via opening, wherein the sum of a thickness of said supplementary dielectric layer and a thickness of said at least one dielectric layer directly above said metal line is substantially equal to a predefined target thickness; and
patterning said supplementary dielectric layer and said at least one dielectric layer directly above said metal line to expose said metal line.

2. The method of claim 1, further comprising forming at least one metallic liner layer directly on said metal line after said metal line is exposed.

3. The method of claim 2, wherein said at least one metallic layer comprises at least one of a TaN layer, a Ti layer, and a TiN layer.

4. The method of claim 2, wherein said at least one metallic layer comprises a stack, from bottom to top, of a TaN layer, a Ti layer, and a TiN layer.

5. The method of claim 2, further comprising forming a metal layer directly on said at least one metallic layer.

6. The method of claim 5, wherein said metal layer comprise Al and has a thickness from about 0.8 μm to about 3.0 μm.

7. The method of claim 1, wherein said at least one dielectric layer comprises:
a dielectric cap layer abutting said metal line and said interconnect level dielectric layer;
a first dielectric layer abutting said dielectric cap layer; and
a second dielectric layer abutting said first dielectric layer.

8. The method of claim 7, wherein said second dielectric layer and said supplementary dielectric layer comprise a same material.

9. The method of claim 8, wherein said first dielectric layer comprises silicon oxide and said second dielectric layer comprises silicon nitride.

10. A method of modifying an interconnect structure comprising:
providing an interconnect structure comprising:
a metal line embedded in an interconnect level dielectric layer;
at least one dielectric layer containing a via opening, wherein a via opening is separated from said metal line by said at least one dielectric layer; and
at least one metallic liner located directly on said at least one dielectric layer and filling said via opening; and
a metal layer located directly on said at least one metallic liner;
removing said metal layer and said at least one metallic liner selective to said at least one dielectric layer and exposing said via opening;
forming a supplementary dielectric layer in said via opening, wherein the sum of a thickness of said supplementary dielectric layer and a thickness of said at least one dielectric layer directly above said metal line is substantially equal to a predefined target thickness; and
patterning said supplementary dielectric layer and said at least one dielectric layer directly above said metal line to expose said metal line.

11. The method of claim 10, further comprising forming at least one metallic liner layer directly on said metal line after said metal line is exposed.

12. The method of claim 11, wherein said at least one metallic layer comprises at least one of a TaN layer, a Ti layer, and a TiN layer.

13. The method of claim 11, wherein said at least one metallic layer comprises a stack, from bottom to top, of a TaN layer, a Ti layer, and a TiN layer.

14. The method of claim 11, further comprising forming a metal layer directly on said at least one metallic layer.

15. The method of claim 14, wherein said metal layer comprise Al and has a thickness from about 0.8 g/m to about 3.0 μm.

16. The method of claim 10, wherein said at least one dielectric layer comprises:
a dielectric cap layer abutting said metal line and said interconnect level dielectric layer;
a first dielectric layer abutting said dielectric cap layer; and
a second dielectric layer abutting said first dielectric layer.

17. The method of claim 16, wherein said second dielectric layer and said supplementary dielectric layer comprise a same material.

18. The method of claim 17, wherein said first dielectric layer comprises silicon oxide and said second dielectric layer comprises silicon nitride.

19. A method of modifying an interconnect structure comprising:
providing an interconnect structure comprising:
a metal line embedded in an interconnect level dielectric layer; and
at least one dielectric layer containing a via opening, wherein a via opening is separated from said metal line by said at least one dielectric layer;
forming a supplementary dielectric layer in said via opening, wherein the sum of a thickness of said supplementary dielectric layer and a thickness of said at least one dielectric layer directly above said metal line is substantially equal to a predefined target thickness; and
patterning said supplementary dielectric layer and said at least one dielectric layer directly above said metal line to expose said metal line.

20. The method of claim 19, further comprising forming at least one metallic liner layer directly on said metal line after said metal line is exposed.

21. The method of claim 20, wherein said at least one metallic layer comprises at least one of a TaN layer, a Ti layer, and a TiN layer.

22. The method of claim 20, wherein said at least one metallic layer comprises a stack, from bottom to top, of a TaN layer, a Ti layer, and a TiN layer.

23. The method of claim 19, wherein said at least one dielectric layer comprises:
a dielectric cap layer abutting said metal line and said interconnect level dielectric layer;
a first dielectric layer abutting said dielectric cap layer; and
a second dielectric layer abutting said first dielectric layer.

24. The method of claim 23, wherein said second dielectric layer and said supplementary dielectric layer comprise a same material.

25. The method of claim 24, wherein said first dielectric layer comprises silicon oxide and said second dielectric layer comprises silicon nitride.
